(19) United States
(12) Patent Application Publication
(10) Pub. No.: US 2025/0239446 A1
(43) Pub. Date: Jul. 24, 2025

(54) SUBSTRATE-TREATMENT METHOD AND SUBSTRATE-TREATMENT SYSTEM

(71) Applicant: Tokyo Electron Limited, Tokyo (JP)

(72) Inventors: Isao GUNJI, Yamanashi (JP); Masahiro OKA, Yamanashi (JP); Takashi KOBAYASHI, Yamanashi (JP)

(21) Appl. No.: 19/173,055

(22) Filed: Apr. 8, 2025

Related U.S. Application Data
(63) Continuation of application No. PCT/JP2023/036850, filed on Oct. 11, 2023.

(30) Foreign Application Priority Data
Oct. 25, 2022 (JP) 2022-170874

(51) Int. Cl. H01L 21/02; C23C 16/40; C23C 16/458; C23C 16/52; C23C 16/56; H01J 37/32; H01L 21/311; H01L 21/768

(52) U.S. Cl. CPC H01L 21/0234; C23C 16/401; C23C 16/4583; C23C 16/52; C23C 16/56; H01L 21/02164; H01L 21/31116; H01L 21/76843; H01J 37/32192; H01J 2237/336

(57) ABSTRACT

A substrate-treatment method includes (a) providing a substrate at a stage, the substrate including a silicon nitride-containing film, in which a recess defined by a top, a side wall, and a bottom is formed, and a silicon film exposed from the bottom of the recess; (b) forming a silicon oxide film along the recess; (c) exposing the silicon oxide film to a plasma of a process gas containing a hydrogen gas, thereby modifying the silicon oxide film at the top and bottom of the recess selectively relative to the side wall by an anisotropic plasma treatment; and (d) selectively removing the modified silicon oxide film at the top and bottom of the recess through chemical etching without using a plasma, thereby retaining the silicon oxide film at the side wall of the recess.

### CROSS-REFERENCE TO RELATED APPLICATIONS

This application is a continuation application of International Application No. PCT/JP2023/036850, filed on Oct. 11, 2023, and designated the U.S., which is based upon and claims priority to Japanese Patent Application No. 2022-170874, filed on Oct. 25, 2022, the entire contents of which are incorporated herein by reference.

### BACKGROUND

### 1. Field of the Invention

The present disclosure relates to a substrate-treatment method and a substrate-treatment system.

### 2. Description of the Related Art

For example, Japanese Laid-Open Patent Application Publication No. 2017-208469 proposes to perform the following to a treatment target substrate including an insulating film having a predetermined pattern and a silicon-containing oxide film formed at a silicon portion at the bottom of the pattern: removing the silicon-containing oxide film, forming a metal film after the removal of the silicon-containing oxide film, and reacting the silicon portion with the metal film, thereby forming a contact at the bottom of the pattern.

### SUMMARY

According to an aspect of the present disclosure, a substrate-treatment method is provided. The substrate-treatment method includes: (a) providing a substrate at a stage, the substrate including a silicon nitride-containing film, in which a recess defined by a top, a side wall, and a bottom is formed, and a silicon film exposed from the bottom of the recess; (b) forming a silicon oxide film along the recess; (c) exposing the silicon oxide film to a plasma of a process gas containing a hydrogen gas, thereby modifying the silicon oxide film at the top and bottom of the recess selectively relative to the side wall by an anisotropic plasma treatment; and (d) selectively removing the modified silicon oxide film at the top and bottom of the recess through chemical etching without using a plasma, thereby retaining the silicon oxide film at the side wall of the recess.

### BRIEF DESCRIPTION OF THE DRAWINGS

FIGS. 1A, 1B, 1C, and 1D are cross-sectional views of a film structure describing an example of an existing substrate-treatment method;

FIG. 2 is a flowchart illustrating an example of a substrate-treatment method according to an embodiment;

FIGS. 3A, 3B, 3C, 3D, and 3E are cross-sectional views of a film structure describing the substrate-treatment method of FIG. 2;

FIG. 4 is a flowchart illustrating an example of subsequent steps following the substrate-treatment method of FIG. 2;

FIGS. 5A, 5B, 5C, and 5D are cross-sectional views of a film structure describing a substrate-treatment method of FIG. 4;

FIG. 6 is a view illustrating a configuration example of a substrate-treatment system according to an embodiment;

FIG. 7 is a configuration example of a processor of a first process chamber in the substrate-treatment system; and

FIG. 8 is a configuration example of a processor of a second process chamber in the substrate-treatment system.

### DETAILED DESCRIPTION OF THE DISCLOSURE

The present disclosure provides a technique of realizing a desired substrate treatment while protecting a side wall of a recess in a silicon nitride-containing film formed at a substrate.

Hereinafter, embodiments of the present disclosure will be described with reference to the drawings. In the drawings, the same components are denoted by the same reference symbols, and thus duplicate description may be omitted.

In the present specification, directions of being parallel, a right angle, orthogonal, horizontal, vertical, upward-downward, rightward-leftward, and the like permit such deviations as not to impair the effects of the embodiments. The shape of a corner is not limited to a right angle, but may be rounded in the form of a bow. Being parallel, a right angle, orthogonal, horizontal, vertical, circular, and identical may include being substantially parallel, substantially a right angle, substantially orthogonal, substantially horizontal, substantially vertical, substantially circular, and substantially identical.

### Existing Substrate-Treatment Method

There is a substrate-treatment method including embedding a metal film in a recess in a film structure in which a silicon film serving as an underlying film is exposed from the bottom of the recess formed in a silicon nitride-containing film (e.g., a silicon nitride film (SiN)), thereby forming an interconnect structure of the metal film at a contact at the bottom of the recess. Examples include a substrate-treatment method that realizes formation of a metal interconnect connected to a contact of a source/drain.

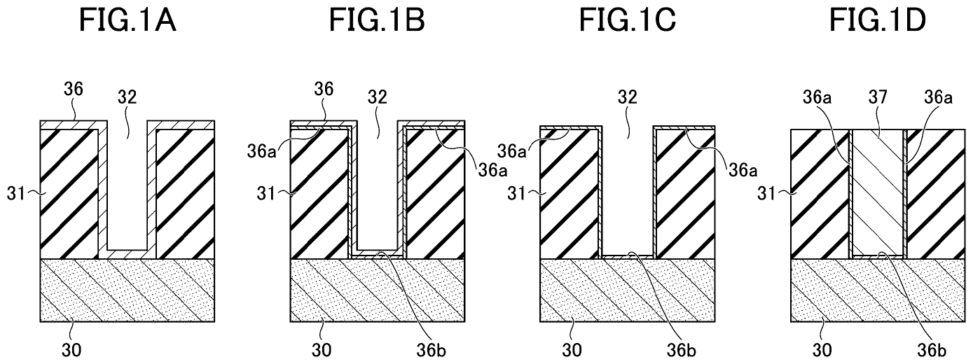

In the existing substrate-treatment method of forming the interconnect at the contact, as illustrated in FIG. 1A, a titanium (Ti) film 36 is formed along a recess 32 in a film structure in which a silicon film 30 serving as an underlying film is exposed from the bottom of the recess 32 formed in a silicon nitride film 31.

However, the titanium film 36 is highly reactive with the silicon nitride film 31, and as illustrated in FIG. 1B, the titanium film 36 formed over the silicon nitride film 31 reacts with the silicon nitride film 31, thereby forming a compound of a titanium nitride silicide (TiSiN) film 36a. Also, the titanium film 36 formed over the silicon film 30 by heating the substrate or without heating the substrate reacts with the silicon film 30, thereby forming a compound of a titanium silicide (TiSi) film 36b.

In this case, when the titanium film 36 is to be removed through wet etching in a subsequent step, as illustrated in FIG. 1C, the titanium nitride silicide film 36a remains along with the titanium silicide film 36b at the contact of the silicon film 30. Due to selectivity between the titanium silicide film 36b and the titanium film 36, the titanium film 36 can be removed while retaining the titanium silicide film 36b. On the other hand, due to substantially no selectivity between the titanium nitride silicide film 36a and the titanium silicide film 36b, it is challenging to remove the titanium nitride silicide film 36a while retaining the titanium silicide film 36b.

In this state, as illustrated in FIG. 1D, when a tungsten (W) film 37 is formed and further the top is planarized, a resistance value of the resulting metal interconnect increases due to the resistance of the titanium nitride silicide film 36a, which is an insulating film.

Furthermore, in recent years, in response to requests for miniaturization, the width of the recess 32 becomes smaller and the aspect ratio becomes larger. Therefore, when the titanium nitride silicide film 36a is formed at the side wall of the recess 32, the width of the recess 32 becomes even smaller, and thus it becomes more challenging to remove the titanium nitride silicide film 36a through wet etching.

In view of the above, the present disclosure proposes a substrate-treatment method that realizes a desired substrate treatment, such as, for example, forming a metal film at the bottom of the recess 32 while protecting the side wall of the recess 32 of the silicon nitride-containing film formed at the substrate.

### Substrate-Treatment Method According to Embodiment

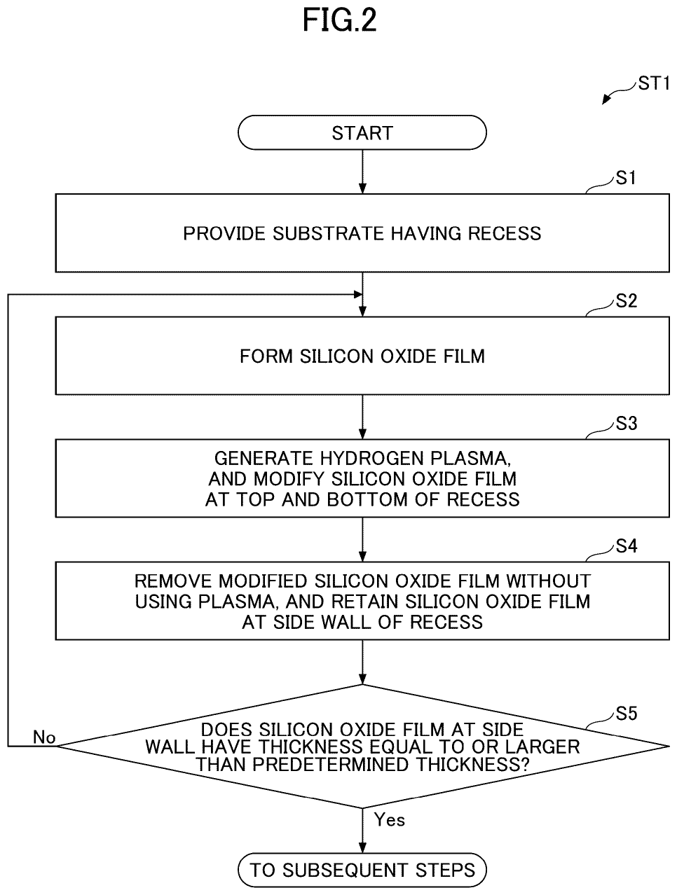

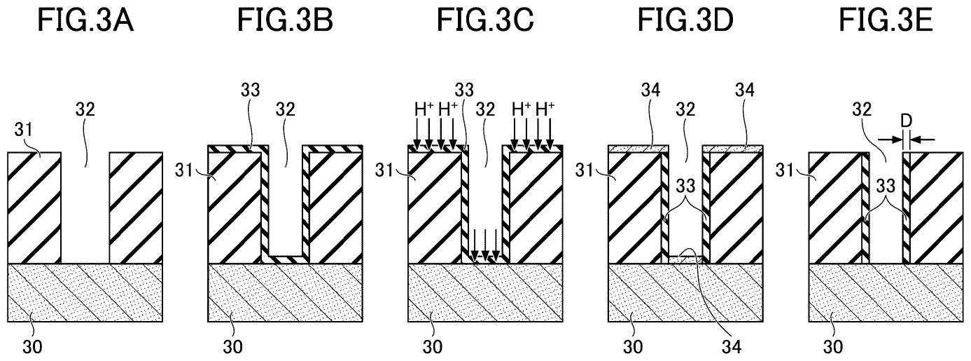

A substrate-treatment method ST1 according to an embodiment will be described with reference to FIG. 2 and FIGS. 3A to 3E. FIG. 2 is a flowchart illustrating an example of the substrate-treatment method ST1 according to the embodiment. FIGS. 3A to 3E are cross-sectional views describing the substrate-treatment method ST1 of FIG. 2.

### Step S1

According to the substrate-treatment method ST1 according to the embodiment illustrated in FIG. 2, in step S1, a substrate, e.g., a semiconductor wafer, is transferred into a process chamber (referred to as a first process chamber) described below, and is placed and provided at a stage in the first process chamber.

FIG. 3A is an example of an initial state of the film structure over the substrate to be provided. The substrate includes: the silicon nitride film 31 having the recess 32 defined by the top, the side wall, and the bottom; and the silicon film 30 serving as an underlying film of the silicon nitride film 31 and being exposed from the bottom of the recess 32. The silicon nitride film 31 is an example of the silicon nitride-containing film. The silicon nitride-containing film is not limited to the silicon nitride film (SiN), but may be a SiCN film. The recess 32 may be a trench, a via hole, a contact hole, or the like.

### Step S2

Next, in step S2, a process gas is supplied into the first process chamber described below, and a silicon oxide film 33 is formed along the recess 32 formed over the substrate. As a result, as illustrated in FIG. 3B, the silicon oxide film 33 is formed along the top, side wall, and bottom of the recess 32.

An example of a process condition for step S2 is presented below.

Formation of Silicon Oxide Film: Process condition
Temperature of the stage: 500 degrees Celsius (° C.) or less
Pressure: 5 pascal (Pa) to 133.3 pascal (Pa)
Process gases: raw material gas and reaction gas
   Raw material gas: tetraethoxysilane (TEOS: Si(OC₂H₅)₄)
   Reaction gas: O₂ gas
Other examples of the raw material gas include dichlorosilane (DCS: SiH₂Cl₂), monochlorosilane (MCS: SiH₃Cl), trichlorosilane (TCS: SiHCl₃), silicon tetrachloride (STC: SiCl₄), hexachlorodisilane (HCD: Si₂Cl₆), tris (dimethylamino) silane gas (3DMAS), and the like.

Other examples of the reaction gas include an ozone gas (O₃ gas), a gas mixture of an O₂ gas and a H₂ gas, and the like.

In step S2, a silicon oxide film can be formed by using thermal CVD, plasma CVD, thermal ALD, or plasma ALD, as a film-forming method. When thermal ALD or plasma ALD is used, the silicon oxide film 33 can be formed to be more conformal.

When thermal CVD or plasma CVD is used, the silicon oxide film 33 is less conformal than when thermal ALD or plasma ALD is used. However, it is possible to increase a film-forming rate, a throughput, and productivity. In other words, although ALD is preferable in terms of forming the silicon oxide film 33 as a conformal film, it may be possible to use CVD that can increase the film-forming rate. This is because the silicon oxide film 33 does not need to be a conformal film as long as the silicon oxide film 33 can cover the side wall of the recess 32. Note that thermal ALD and thermal CVD are thermal treatments and thus generate no plasma, while plasma CVD and plasma ALD are plasma treatments.

### Step S3

Next, in step S3, a process gas containing a hydrogen gas is supplied into a process chamber (referred to as a second process chamber), and the silicon oxide film 33 is exposed to a hydrogen plasma, thereby modifying the silicon oxide film 33 at the top and bottom of the recess 32 selectively relative to the side wall by an anisotropic plasma treatment.

An example of a process condition for step S3 is presented below.

### Selective Modification of Silicon Oxide Film: Process Condition

Temperature of the stage: temperature range in step S2 (preceding step) or step S4 (subsequent step)
Pressure: 5 Pa to 133.3 Pa
Process gases: H₂, NH₃, and dilution gas (Ar, He, or the like)
H₂ flow rate: 20 standard cubic centimeter/min (sccm) to 200 standard cubic centimeter/min (sccm)
NH₃ flow rate: 20 sccm to 200 sccm
Ar (dilution gas) flow rate: 10 sccm to 200 sccm
Plasma: present
Microwave power: 100 watt (W) to 3,000 watt (W)
RF power: 100 W to 500 W

In step S3, a microwave power is supplied to the second process chamber, thereby generating a plasma of the process gas containing the hydrogen gas. Then, as illustrated in FIG. 3C, the silicon oxide film 33 is exposed to the plasma containing the hydrogen gas.

In step S3, the anisotropic plasma treatment of implanting hydrogen ions (H⁺) in the vertical direction is performed, thereby performing a selective treatment (modification) to the top and bottom of the silicon oxide film 33. To do this, at least one of the following controls is performed, i.e., the internal pressure of the second process chamber is controlled to be less than the pressure at the time of formation of the silicon oxide film in step S2 (e.g., 133.3 Pa or less), or an RF power (RF bias) is supplied to the stage in the second process chamber.

By controlling at least one of the pressure or the RF power, the amount and angle of hydrogen ions can be controlled. For example, at a pressure higher than 133.3 Pa, the verticality of ions is lost due to scattering. Therefore, in step S3, by setting the pressure to a low pressure of 133.3 Pa or less, it is possible to ensure the verticality of hydrogen ions. However, when the pressure is too low, a plasma cannot be maintained. Therefore, it is preferable to control the pressure to be 5 Pa to 133.3 Pa. Also, for example, by applying the RF power to the stage, the substrate over the stage can draw in hydrogen ions traveling in the vertical direction. However, when the force to draw in hydrogen ions is too high, the contact at the bottom of the recess 32 is damaged by hydrogen ions. Therefore, preferably, the RF power supplied to the stage in the second process chamber is not too high, e.g., about 100 W to about 500 W.

This can increase the verticality of hydrogen ions, and realize an anisotropic plasma treatment. As a result, as illustrated in FIG. 3C, the silicon oxide film 33 exists in the horizontal direction at the top and bottom of the silicon oxide film 33, and thus the silicon oxide film 33 is doped with a larger amount of hydrogen ions. On the other hand, the silicon oxide film 33 exists in the vertical direction at the side wall, and thus doping with hydrogen ions is not readily performed. Thus, as illustrated in FIG. 3D, the silicon oxide film 34 at the top and bottom of the recess 32 is doped with hydrogen ions, resulting in the silicon oxide film 34 that is modified. On the other hand, the silicon oxide film 33 at the side wall of the recess 32 is hardly doped with hydrogen ions, and thus the silicon oxide film 33 at the side wall can be kept as it is.

### Step S4

Next, in step S4, the modified silicon oxide film 34 at the top and bottom of the recess 32 is selectively removed through chemical etching without using a plasma, thereby retaining the silicon oxide film 33 at the side wall of the recess 32. In a step of performing the chemical etching without using a plasma, chemical oxide removal (COR) is performed in a third process chamber described below, and then a post heat treatment (PHT) is performed in a fourth process chamber described below.

An example of a process condition for step S4 is presented below.

### Selective Removal of Modified Silicon Oxide Film: Process Condition

### Process Condition for COR

Process gases: NH₃ and HF
Temperature of the stage: 20° C. or less
Plasma: absent

In the COR, the modified silicon oxide film 34 is changed to a readily vaporizable substance without using a plasma, as indicated in the following chemical reaction formula. In the COR of step S4, the silicon oxide film 34 is exposed to an NH₃ gas and a HF gas. As a result, the silicon oxide film 34 is changed to ammonium silicofluoride ((NH₄)₂SiF₆), which is a readily vaporizable product. The chemical reaction formula at this time is as follows.

SiO₂ (Solid)+2NH₃ (gas)+6HF (gas)→(NH₄)₂SiF₆ (Solid)+2H₂O (gas)

The NH₃ gas and the HF gas are examples of the process gases supplied in the present step, and are by no means limitations. Any process gas can be used as long as fluorine and hydrogen are contained.

(Process Condition for PHT) Temperature of the stage: 80° C. or more

In the PHT, the ammonium silicofluoride formed in the COR is thermally treated to form gases of SiF₄, HF, and NH₃, followed by removal. The chemical reaction formula at this time is as follows.

(NH₄)₂SiF₆ (Solid)→SiF₄↑+2NH₃↑+2HF↑
Thus, the modified silicon oxide film 34 at the top and bottom of the recess 32 is removed through chemical etching.

The modified silicon oxide film 34 has an etching rate higher than that of the silicon oxide film 33 that is not modified. Thus, as illustrated in FIG. 3E, it is possible to realize selective etching in which the modified silicon oxide film 34 at the top and bottom of the recess 32 is selectively removed while retaining the unmodified silicon oxide film 33 at the side wall of the recess 32. In step S4, no plasma is used, and thus the silicon oxide film 34 at the bottom can be removed while minimizing damage to the contact at the bottom of the recess 32.

### Step S5

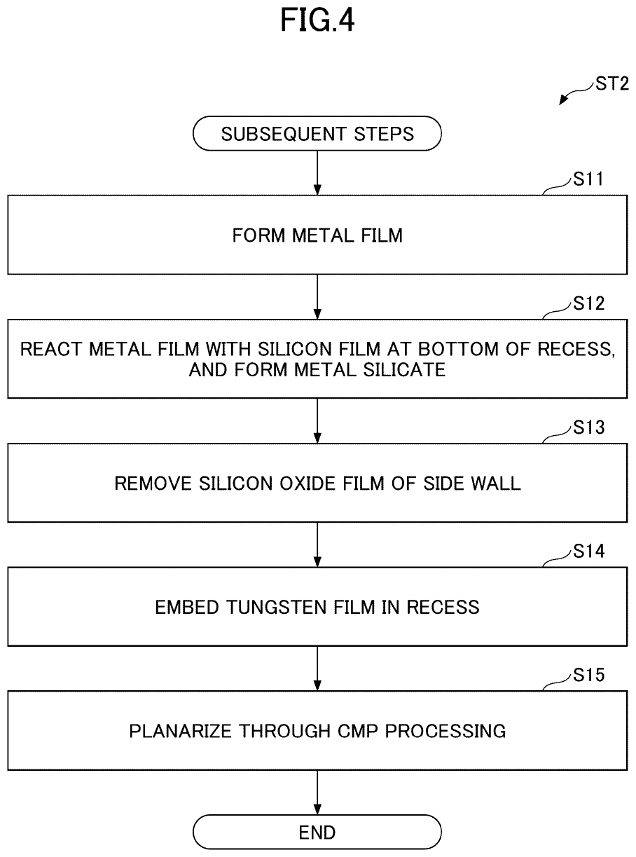

Next, in step S5, it is determined whether or not the silicon oxide film 33 at the side wall has a thickness equal to or larger than a predetermined thickness. The silicon oxide film 33 at the side wall may be slightly etched in step S4. Therefore, if it is determined that a thickness D of the silicon oxide film 33 at the side wall illustrated in FIG. 3E is less than the predetermined thickness, the process is returned to step S2, and steps S2, S3, and S4 are repeated in this order. If it is determined that the thickness D of the silicon oxide film 33 at the side wall is equal to or larger than the predetermined thickness in step S5, the process proceeds to the subsequent steps illustrated in FIG. 4. Thus, it is possible to form the silicon oxide films 33 having the predetermined thickness at the side wall while removing the silicon oxide film 34 at the top and bottom. Step S5 may be omitted.

According to the substrate-treatment method ST1 according to the embodiment described above, a desired substrate treatment in the subsequent steps can be realized by retaining the silicon oxide film 33 at the side wall, i.e., protecting the side wall of the recess 32.

### Subsequent Steps

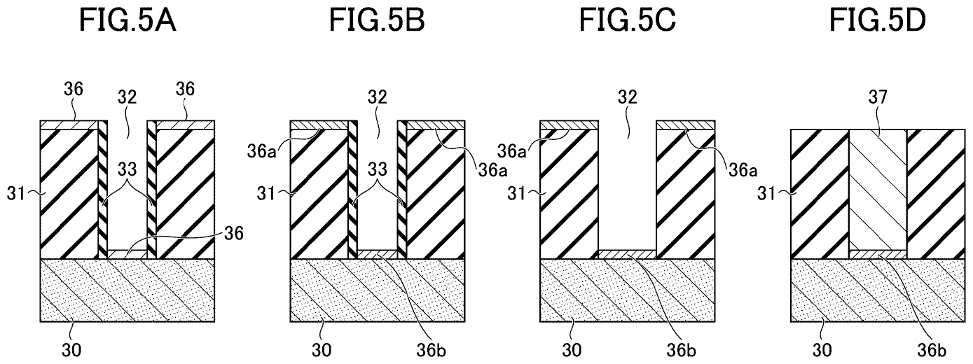

Next, the subsequent steps, in which a desired substrate treatment is performed while protecting the side wall of the recess 32 by the silicon oxide film 33 at the side wall, will be described with reference to FIG. 4 and FIGS. 5A to 5D. In the following, formation of a metal film in the recess 32 will be described as an example of the subsequent steps. However, the desired substrate treatment in the subsequent steps is not limited to the formation of the metal film in the recess 32. FIG. 4 is a flowchart illustrating an example of the subsequent steps, i.e., a substrate-treatment method ST2, following the substrate-treatment method ST1 of FIG. 2. FIGS. 5A to 5D are cross-sectional views of a film structure describing the substrate-treatment method ST2 of FIG. 4.

### Step S12

In step S11 of FIG. 4, a metal film is formed in the recess 32 in a state in which the silicon oxide film 33 is formed at the side wall of the recess 32 illustrated in FIG. 3E. As an example of the metal film, the titanium (Ti) film 36 is formed.

An example of a process condition for step S11 is presented below.

### Formation of Titanium Film: Process Condition

Temperature of the stage: 300° C. to 600° C.
Pressure: 1 Torr to 20 Torr
Gases: TiCl₄, H₂, NH₃, and Ar
Plasma: present
Microwave power: not applicable

RF power: 100 W to 1,000 W

According to this, as illustrated in FIG. 5A, the titanium film 36 is formed at the top and bottom of the recess 32 by a plasma of the process gases, i.e., TiCl₄, H₂, NH₃, and Ar. Thus, it is possible to form the titanium film 36 at the contact at the bottom without forming the titanium film 36 at the side wall.

In step S11, the titanium film 36 can be formed over the silicon oxide film 33 at the side wall. However, TiCl₄, forming a raw material gas of the titanium film 36, serves as an etching gas. Therefore, the titanium film 36 can be selectively formed over the silicon film 30 due to the difference between etching rates. In other words, the rate at which the titanium film 36 is formed over the silicon film 30 is substantially higher than the rate at which the titanium film 36 is formed over the silicon oxide film 33. By utilizing this effect, it is possible to perform a control to form the titanium film 36 over a non-oxide, such as the silicon film 30 or the like, at the bottom of the recess 32 without forming the titanium film 36 over the silicon oxide film 33 at the side wall of the recess 32.

Even if the titanium film 36 is slightly formed over the silicon oxide film 33 at the side wall of the recess 32, reactivity is different between the titanium film 36 over the silicon oxide film 33 and the titanium film 36 over the non-oxide, such as the silicon film 30 or the like. That is, a reaction between the silicon oxide film 33 and the titanium film 36 does not readily occur, and thus a compound of titanium oxide silicide (TiSiO) is not readily formed. On the other hand, a reaction between the titanium film 36 and the non-oxide, such as the silicon film 30 or the like, readily occurs, and thus a compound of titanium silicide (TiSi) is readily formed. As a result, it is possible to prevent formation of insulating products in the recess 32, such as titanium nitride silicide (TiSiN), titanium oxide silicide (TiSiO), and the like, which cause resistance in a resulting metal interconnect.

### Step S12

Next, in step S12, the titanium film 36 is reacted with the silicon film 30 exposed from the bottom of the recess 32, thereby forming the titanium silicide (TiSi) film 36b. In step S12, the substrate may be heated to silicide the titanium film 36 formed over the silicon film 30, thereby forming the titanium silicide film 36b. When the substrate is heated, the temperature of the stage is controlled to be 400° C. to 600° C. The titanium film 36 can be silicided without heating the substrate, but some of the titanium film 36 might remain unchanged. By heating the substrate, the titanium film 36 is silicided, and the titanium film 36 over the silicon film 30 can be reliably formed into the titanium silicide film 36b.

When the titanium film 36 at the top of the recess 32 is silicided, the titanium nitride silicide (TiSiN) film 36a is formed. The titanium silicide (TiSi) film 36b is an example of a metal silicate. Thus, as illustrated in FIG. 5B, the titanium

silicide (TiSi) film 36b is formed at the bottom of the recess 32, and the titanium nitride silicide (TiSiN) film 36a is formed at the top. On the other hand, at the side wall, the silicon oxide film 33 serves as a protective film, and a titanium film or a compound in which the titanium film is silicided is not formed.

### Step S13

Next, in step S13, the silicon oxide film 33 at the side wall is removed through wet etching using DHF or the like. Plasma: absent

The silicon oxide film 33 at the side wall and the titanium silicide (TiSi) film 36b have different etching rates. Therefore, as illustrated in FIG. 5C, the silicon oxide film 33 having a relatively high etching rate can be removed from the side wall, and the titanium silicide (TiSi) film 36b having a relatively low etching rate can be kept at the bottom.

### Step S14

Next, in step S14, for example, the tungsten film 37 is embedded in the recess 32 as an interconnect layer. The silicon oxide film 33 is removed in step S13, and thus the width of the recess 32 can be increased by the thickness of the silicon oxide film 33.

### Step S15

Next, in step S15, the top of the recess 32 and the top of the tungsten film 37 are planarized through CMP, and the present process is ended. As illustrated in FIG. 5D, the titanium nitride silicide (TiSiN) film 36a is removed, and the top of the recess 32 and the top of the tungsten film 37 can be planarized in a state in which the tungsten film 37 is embedded in the recess 32.

According to the substrate-treatment methods ST1 and ST2 described above, a metal interconnect having a small amount of resistance components can be formed.

### Substrate-Treatment System

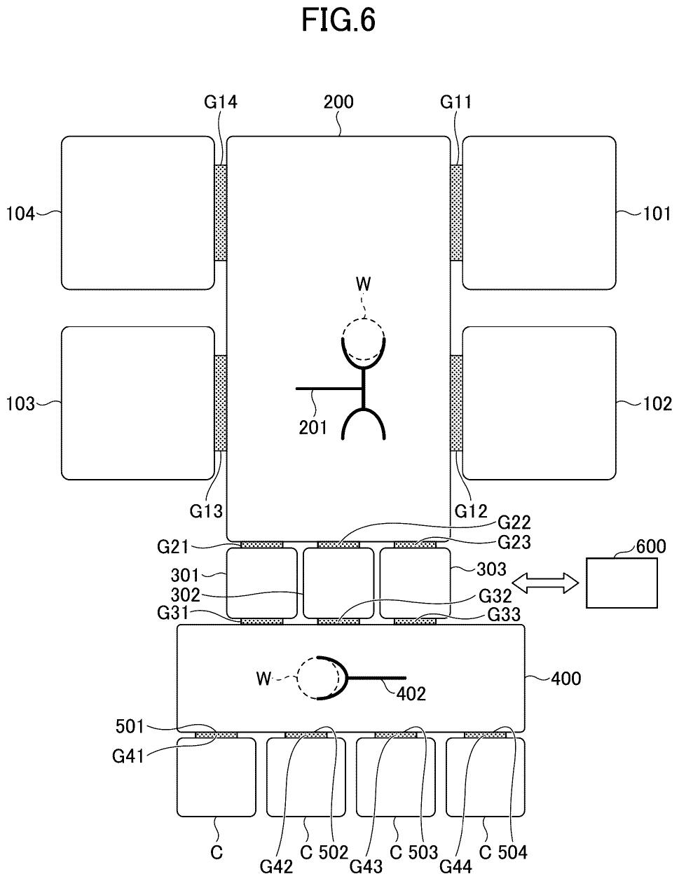

Next, a configuration example of a substrate-treatment system including a plurality of process chambers configured to perform the substrate-treatment method ST1 will be described with reference to FIG. 6. In the following, the configuration example of the substrate-treatment system having four process chambers will be described. However, the number of process chambers is not limited to four as long as the number of process chambers is three or more. FIG. 6 is a view illustrating the configuration example of the substrate-treatment system according to the embodiment.

The substrate-treatment system performs the substrate-treatment method ST1 of the present disclosure. The substrate-treatment system may further perform the substrate-treatment method ST2 of the present disclosure. However, the configuration of the substrate-treatment system illustrated in FIG. 6 is merely an example, and can be any other configuration. The substrate-treatment system includes processors 101 to 104, a vacuum transfer chamber 200, load lock chambers 301 to 303, an atmosphere transfer chamber 400, load ports 501 to 504, and a controller 600.

The processors 101 to 104 are connected to the vacuum transfer chamber 200 through gate valves G11 to G14, respectively. The interiors of the processors 101 to 104 are reduced to a predetermined vacuum atmosphere, and a substrate W is subjected to a desired treatment in the interiors of the processors 101 to 104.

The processor 101 is an example of a substrate-treatment apparatus configured to perform step S2 of FIG. 2 in the first process chamber, and form the silicon oxide film 33 along the recess 32 of the substrate W. The processor 102 is an example of a substrate-treatment apparatus configured to perform step S3 of FIG. 2 in the second process chamber, and expose the silicon oxide film 33 to a plasma of a process gas containing a hydrogen gas, thereby modifying the silicon oxide film 34 at the top and bottom of the recess 32 selectively relative to the side wall by an anisotropic plasma treatment.

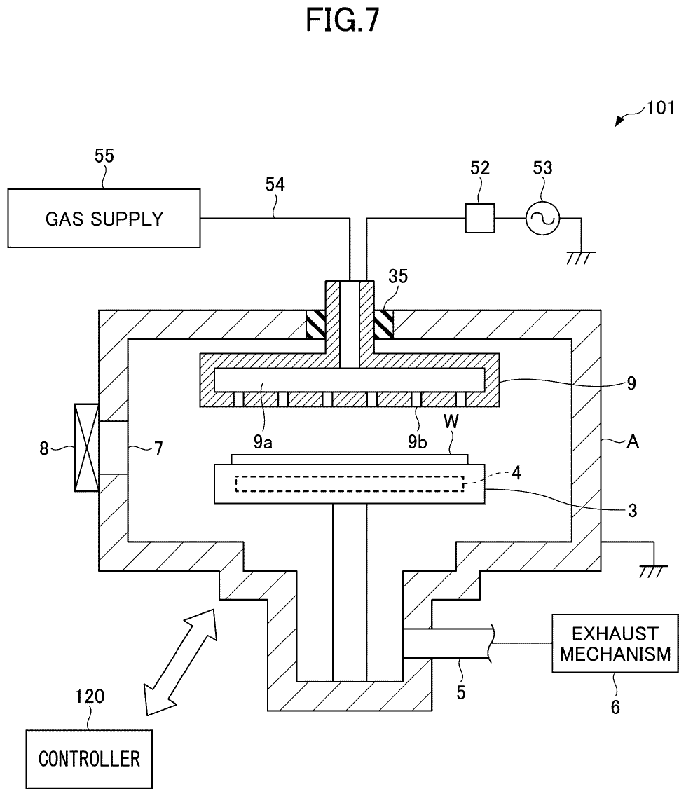

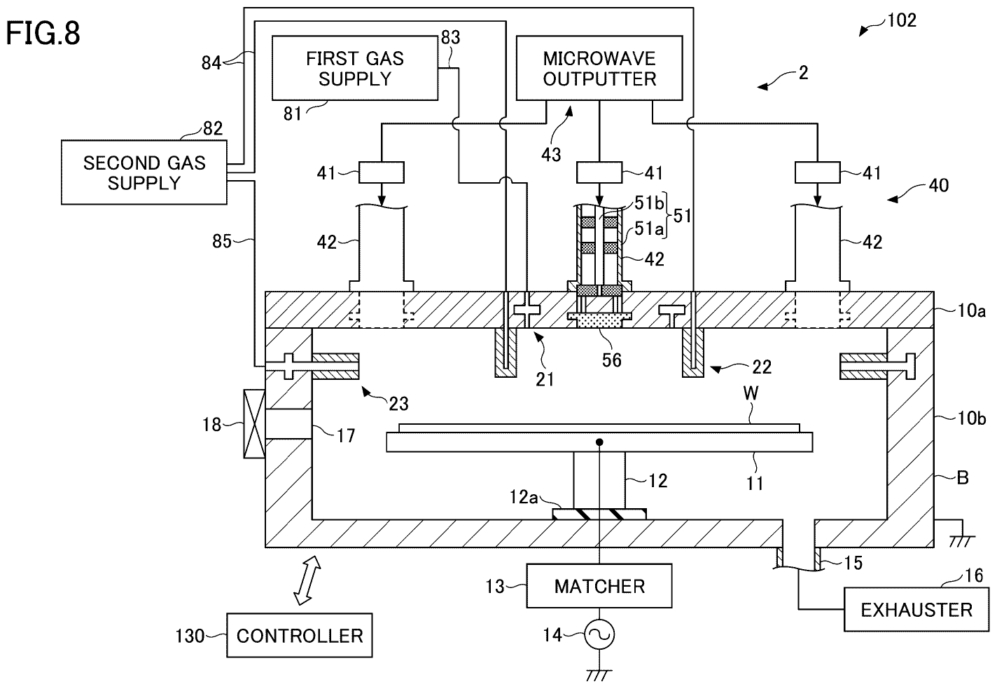

The processors 103 and 104 are examples of the third and fourth process chambers configured to perform step S4 of FIG. 2 in the third and fourth process chambers, thereby removing the modified silicon oxide film 34. For example, the processor 103 performs the COR in the third process chamber. The processor 104 performs the PHT in the fourth process chamber. A configuration example of the processor 101 will be described below with reference to FIG. 7. A configuration example of the processor 102 will be described below with reference to FIG. 8.

The interior of the vacuum transfer chamber 200 is reduced to a predetermined vacuum atmosphere. The vacuum transfer chamber 200 is provided with a transfer mechanism 201 configured to transfer the substrate W under reduced pressure. The transfer mechanism 201 transfers the substrate W to the processors 101 to 104 and the load lock chambers 301 to 303. The transfer mechanism 201 includes, for example, two transfer arms. However, the number of transfer arms may be one.

The load lock chambers 301 to 303 are connected to the vacuum transfer chamber 200 through gate valves G21 to G23, respectively, and are connected to the atmosphere transfer chamber 400 through gate valves G31 to G33, respectively. The interiors of the load lock chambers 301 to 303 can be changed between a normal atmosphere and a vacuum atmosphere.

The interior of the atmosphere transfer chamber 400 is a normal atmosphere, and forms, for example, a downflow of clean air. An aligner (not shown) configured to perform alignment of the substrate W is provided in the atmosphere transfer chamber 400. The atmosphere transfer chamber 400 is provided with a transfer mechanism 402. The transfer mechanism 402 includes, for example, one transfer arm. However, the number of transfer arms may be two or more. The transfer mechanism 402 is configured to transfer the substrate W to the load lock chambers 301 to 303, carriers C of the load ports 501 to 504 described below, and the aligner.

The load ports 501 to 504 are provided at a wall of a long side of the atmosphere transfer chamber 400. The load ports 501 to 504 are provided, through gate valves G41 to G44, with the carriers C housing the substrate W or with the empty carriers C. For example, a front opening unified pod (FOUP) can be used as the carrier C.

The controller 600 is configured to control respective components of the substrate-treatment system. For example, the controller 600 controls movements of the processors 101 to 104, movements of the transfer mechanisms 201 and 402, opening and closing of the gate valves G11 to G14, G21 to G23, G31 to G33, and G41 to G44, and switching of the atmosphere in the load lock chambers 301 to 303.

As described above, the substrate-treatment system 1 illustrated in FIG. 6 includes a plurality of process chambers (the processors 101 to 104), a vacuum transfer chamber (the vacuum transfer chamber 200) configured to transfer a substrate in vacuum between the plurality of process chambers, and the controller 600. The controller 600 is configured to control a process including: providing the substrate W (see FIG. 3A) at a stage 3 of the first process chamber (the processor 101) and forming the silicon oxide film 33 along the recess 32 (see FIG. 3B), the substrate W including the silicon nitride-containing film (the silicon nitride film 31 in the example of FIGS. 3A to 3E), in which the recess 32 defined by the top, the side wall, and the bottom is formed, and the silicon film 30 exposed from the bottom of the recess 32; after the formation of the silicon oxide film 33, providing the substrate W at a stage (susceptor 11) of the second process chamber (the processor 102), exposing the silicon oxide film 33 to a plasma of a process gas containing a hydrogen gas, modifying the silicon oxide film 33 at the top and bottom of the recess 32 selectively relative to the side wall by an anisotropic plasma treatment, and forming the silicon oxide film 34 doped with hydrogen ions (see FIGS. 3C and 3D); after the selective modification of the silicon oxide film 33, providing the substrate W at a stage of the third process chamber (the processor 103), supplying a process gas containing fluorine and hydrogen to fluorinate the modified silicon oxide film 34 at the top and bottom of the recess 32, thereby forming a fluoride (e.g., ammonium silicofluoride); after the formation of the fluoride, providing the substrate W at a stage of the fourth process chamber (the processor 104) and sublimating the fluoride through heating; and removing the silicon oxide film at the top and bottom of the recess 32 through chemical etching, thereby retaining the silicon oxide film 33 at the side wall of the recess 32. According to the substrate-treatment system 1, it is possible to retain the silicon oxide film 33 at the side wall of the recess 32 without exposing the substrate W to the atmosphere, i.e., without breaking a vacuum state, while the substrate W is treated in the respective process chambers.

### Processor

Next, a configuration example of the processor 101 configured to perform the formation of the silicon oxide film along the recess 32 (step S2 in FIG. 2) will be described with reference to FIG. 7. FIG. 7 is a configuration example of the processor in the substrate-treatment system. The processor 101 includes a first process chamber A.

The processor 101 is an apparatus configured to form the silicon oxide film 33 along the recess 32 under the control of a controller 120 (see FIG. 3B). However, the configuration of the processor 101 illustrated in FIG. 7 is merely an example, and is by no means a limitation. For example, the processor 101 may be a semi-batch-type apparatus configured to revolve a plurality of substrates, disposed over rotating tables in the first process chamber, by revolution of the rotating tables, thereby treating the substrates by sequentially passing the substrates through a region to which the raw material gas is supplied and a region to which the reaction gas is supplied. In the processor 101 illustrated in FIG. 7, the silicon oxide film 33 may be formed through thermal CVD or plasma CVD. In the semi-batch-type apparatus, the silicon oxide film 33 may be formed through thermal ALD or plasma ALD.

The first process chamber A is grounded. The first process chamber A is provided with the stage 3 configured to support the substrate W horizontally. The stage 3 is formed of a metal, and a temperature controller 4 configured to control the temperature of the substrate W is provided in the interior of the stage 3. The stage 3 is grounded through the first process chamber A. The temperature controller 4 is, for example, a heater embedded in the stage 3.

An exhaust tube 5 is connected to the bottom surface of the first process chamber A, and an exhaust mechanism 6, having a function of controlling the internal pressure of the first process chamber A, is connected to the exhaust tube 5. A transfer port 7, through which the substrate W is transferred, is formed in the side wall of the first process chamber A, and the transfer port 7 is opened and closed by a gate valve 8.

A gas shower head 9 is provided at an upper part of the first process chamber A so as to face the stage 3. The gas shower head 9 includes a gas chamber 9a in the interior, and has a plurality of gas discharge holes 9b in the bottom surface. The gas shower head 9 and the top wall of the first process chamber A are insulated by an insulator 35.

A gas supply 55 is connected to the gas shower head 9 through a gas flow path 54. The gas supply 55 is configured to supply the raw material gas, the reaction gas, and the like. The gas supply 55 may supply an inert gas as a carrier gas, a dilution gas, a plasma generation gas, or the like. These process gases reach the gas chamber 9a of the gas shower head 9 from the gas supply 55 through the gas flow path 54, and are discharged into the first process chamber A through the gas discharge holes 9b. An RF (high frequency) power supply 53 is connected to the gas shower head 9 through a matcher 52. The RF power supply 53 is configured to apply, for example, a high-frequency power of 13.56 MHz to the gas shower head 9. When the high-frequency power is applied to the gas shower head 9, a high-frequency electric field is formed between the gas shower head 9 and the stage 3, and a capacitively coupled plasma is generated by the gas discharged from the gas shower head 9.

The processor 101 includes the controller 120. The controller 120 is, for example, a computer, and includes a program storage (not shown). The program storage stores a program that controls the substrate-treatment method in the processor 102. The program may be a program installed in the controller 120 from a computer-readable storage medium in which the program is recorded in advance, such as a computer-readable hard disk (HD), flexible disk (FD), compact disk (CD), magnet optical disk (MO), memory card, or the like.

In the processor 101 having such a configuration, the substrate W is placed over the stage 3, the temperature of the substrate W is controlled to be 500° C. or less by the temperature controller 4, and the raw material gas and the reaction gas are supplied from the gas supply 55 into the first process chamber A through the gas shower head 9. Further, a high-frequency power may be supplied from the RF power supply 53 to the gas shower head 9. Through a thermal treatment or a plasma treatment, the silicon oxide film 33 is formed along the recess 32 of the substrate without occluding the opening of the recess 32 (see FIG. 3B).

### Processor

Next, a configuration example of the processor 102 configured to selectively modifying the silicon oxide film 33 at the top and bottom of the recess 32 will be described with reference to FIG. 8. FIG. 8 is a configuration example of the processor in the substrate-treatment system. The processor 102 includes a second process chamber B.

The processor 102 is configured to perform step S3 of FIG. 2 under the control of a controller 130. Specifically, the processor 102 is configured to supply a process gas containing a hydrogen gas into the second process chamber B under reduced pressure, expose the silicon oxide film 33 to a hydrogen plasma, and modify the silicon oxide film 33 at the top and bottom of the recess 32 selectively relative to the side wall of the recess 32 by an anisotropic plasma treatment (see FIGS. 3C and 3D). The processor 102 is a microwave plasma processor configured to generate a surface wave plasma by microwaves and perform an anisotropic plasma treatment to a substrate. However, the configuration of the processor 102 illustrated in FIG. 8 is merely an example, and is by no means a limitation.

The second process chamber B is a substantially cylindrical container formed of a metal material, such as aluminum or the like, and is grounded. The processor 102 includes a microwave plasma source 2 configured to introduce microwaves into the second process chamber B, thereby forming a surface wave plasma.

A top wall 10a of the second process chamber B

includes a body formed of a metal. Dielectric members of a plurality of microwave radiation mechanisms 42 (the dielectric members are each referred to as a dielectric window 56) are fitted into the body. By this, the microwave plasma source 2 is configured to introduce microwaves into the second process chamber B through the dielectric windows 56 in the top wall 10a.

The second process chamber B is provided with the susceptor (stage) 11 configured to support the substrate W horizontally in a state of being supported by a cylindrical support 12 that is placed upright through an insulator 12a at the center of the bottom of the chamber B. The material forming the susceptor 11 and the support 12 is, for example, a metal, such as aluminum or the like, whose surface is subjected to an alumite treatment (anodizing treatment) or an insulating material (ceramics or the like) including an electrode for high frequencies in the interior.

Although not illustrated, the susceptor 11 is provided with a temperature control mechanism, a gas flow path through which a gas for heat transfer is supplied to the rear surface of the substrate W, a rising and lowering pin configured to rise and lower for transferring the substrate W, and the like. Further, an electrostatic chuck configured to electrostatically adsorb the substrate W may be provided.

Also, an RF power supply 14 is electrically connected to the susceptor 11 through a matcher 13. When an RF power is supplied from the RF power supply 14 to the susceptor 11, ions in the plasma are drawn into the substrate W.

An exhaust tube 15 is connected at a position apart from the center at the bottom of the second process chamber B, and an exhauster 16 including a vacuum pump is connected to the exhaust tube 15. By driving the exhauster 16, it is possible to exhaust the internal gas of the second process chamber B, and reduce the internal pressure of the second process chamber B to a predetermined pressure. A side wall 10b of the second process chamber B is provided with a transfer inlet/outlet 17 through which the substrate W is transferred in or out, and a gate valve 18 configured to open or close the transfer inlet/outlet 17.

Also, the processor 102 includes a first gas shower 21 configured to discharge a predetermined gas from the top wall 10a of the second process chamber B into the second process chamber B, and a second gas shower 22 configured to introduce a gas from a position between the top wall 10a and the susceptor 11. Further, the processor 102 is provided with a third gas shower 23 configured to introduce a gas from a position that is between the top wall 10a and the susceptor 11 in the second process chamber B and is outward of the second gas shower 22.

The first gas shower 21 is configured to receive supply of an excitation gas (plasma generation gas), such as an Ar gas or the like, or of a gas to be dissociated at high energy among the process gases from the first gas supply 81 through a tube 83, and to discharge the supplied gas into the second process chamber B. Also, the second gas shower 22 and the third gas shower 23 are configured to receive supply of a gas to be prevented from being excessively dissociated among the process gases from the second gas supply 82 through a tube 84 and a tube 85, and to discharge the supplied gas into the second process chamber B. For example, a H₂ gas and a dilution gas (Ar, He, or the like) may be supplied from the first gas shower 21, and an NH₃ gas may be supplied from the second gas shower 22 and the third gas shower 23. However, a H₂ gas, an NH₃ gas and a dilution gas (Ar, He, or the like) may be supplied from any of the first gas shower 21 to the third gas shower 23.

The microwave plasma source 2 includes a microwave outputter 43 configured to output microwaves in a manner distributed into a plurality of paths, and a microwave transmitter 40 configured to transmit the microwaves output from the microwave outputter 43.

The microwave outputter 43 includes a microwave power supply, a microwave oscillator, an amplifier, and a distributor. The microwave power supply is configured to supply a power to the microwave oscillator. The microwave oscillator is configured to cause microwaves of a predetermined frequency (e.g., 860 MHz) to perform PLL oscillation or the like. The amplifier is configured to amplify the oscillated microwaves. The distributor is configured to distribute the microwaves amplified by the amplifier while matching the impedance on the input side with the impedance on the output side so as to minimize loss of the microwaves. Rather than 860 MHz, various frequencies in a range of 700 MHz to 3 GHz, such as 915 MHZ or the like, can be used as the frequency of the microwaves.

The microwave transmitter 40 includes a plurality of amplifiers 41, and a plurality of microwave radiation mechanisms 42 provided to correspond to the amplifiers 41. For example, a total of seven microwave radiation mechanisms 42 are disposed, and specifically, one of the microwave radiation mechanisms 42 is disposed at the center of the top wall 10a, and the remaining six microwave radiation mechanisms 42 are disposed at equal intervals at the circumference centered on the microwave radiation mechanism 42 disposed at the center of the top wall 10a. In the present example, the microwave radiation mechanisms 42 are disposed such that the distance between the center microwave radiation mechanism 42 and each of the surrounding microwave radiation mechanisms 42 is equal to each of the distances between the surrounding microwave radiation mechanisms 42.

The amplifiers 41 are each configured to guide the microwaves, distributed by the distributor, to each of the microwave radiation mechanisms 42. The microwave radiation mechanism 42 includes coaxial tubes 51. The coaxial tubes 51 each include a coaxial microwave transmission path formed of a cylindrical outer conductor 51a and a rod-like inner conductor 51b provided at the center of the cylindrical outer conductor 51a. The microwave radiation mechanism 42 includes a power feed antenna (not shown) configured to feed a power and the microwaves, amplified by the amplifier 41, to the coaxial tube 51. Further, the microwave radiation mechanism 42 includes a tuner configured to match the impedance of a load with the characteristic impedance of a microwave power supply, and an antenna configured to radiate microwaves from the coaxial tube into the second process chamber B.

The antenna is provided at the lower end of the coaxial tube 51, and is fitted into a metal part of the top wall 10a of the second process chamber B. The antenna includes the dielectric window 56. The microwaves passing through the dielectric window 56 generate a surface wave plasma directly below the dielectric window 56 in the second process chamber B.

The processor 102 includes the controller 130. The controller 130 is, for example, a computer, and includes a program storage (not shown). The program storage stores a program that controls the substrate-treatment method in the processor 102. The program may be a program installed in the controller 130 from a computer-readable storage medium in which the program is recorded in advance, such as a computer-readable hard disk (HD), flexible disk (FD), compact disk (CD), magnetic optical disk (MO), memory card, or the like.

The processor 102 is configured to supply a microwave power to the second process chamber B, thereby generating a hydrogen plasma. Thus, as illustrated in FIG. 3C, the silicon oxide film 33 is exposed to the plasma, mainly to the hydrogen plasma.

Also, at least one of the following controls is performed: the internal pressure of the second process chamber B is controlled to be a low pressure of 133.3 Pa or lower, or the RF power of 100 W to 300 W is supplied to the susceptor 11. By this, the amount and angle of hydrogen ions can be controlled, and an anisotropic plasma treatment can be realized. Thus, the silicon oxide film 33 at the bottom and top of the recess 32 is selectively doped with hydrogen ions, and the silicon oxide film 33 at the bottom and top of the recess 32 can be modified into the silicon oxide film 34 doped with hydrogen ions. On the other hand, the silicon oxide film 33 can be kept as it is at the side wall of the recess 32.

The above description is based on an example in which step S2 of FIG. 2 is performed in the processor 101 and step S3 of FIG. 2 is performed in the processor 102. However, these steps may be performed in the same processor. In other words, steps S2 and S3 may be performed continuously in the processor 101 or may be performed continuously in the processor 102.

Step S3 can be controlled to be in the temperature range of step S2 or S4. Therefore, by controlling step S3 to be in the temperature range of step S2, steps S2 and S3 can be performed continuously in the processor 101 or 102.

By controlling step S3 to be in the temperature range of step S4 and performing steps S2 and S3 in different processors, it is possible to reduce the time for controlling the temperature of step S4.

The above description is based on an example in which the COR of step S4 is performed in the processor 103 and the PHT of step S5 is performed in the processor 104. However, this example is by no means a limitation. For example, after the COR of step S4 is performed in the processor 103, the PHT of step S5 may be performed in the processor 102.

As described above, according to the substrate-treatment method and substrate-treatment system of the present embodiment, it is possible to realize a desired substrate treatment while protecting the side wall of the recess formed over the substrate with the silicon oxide film 33. The description with reference to FIG. 4 is based, as examples of the desired substrate treatment, on formation of the metal film (titanium film), silicidation of the metal film, removal of the silicon oxide film 33, and embedment of the tungsten film. However, the desired substrate treatment is not limited to these. With increasing miniaturization in treatments, the substrate-treatment method and substrate-treatment system of the present embodiment are applicable to, for example, predetermined substrate treatments (etching, film formation, and the like) while protecting the side wall of a recess having a high aspect ratio with the silicon oxide film 33.

The substrate-treatment method and substrate-treatment system according to the embodiments disclosed herein should be considered to be exemplary in all respects and not restrictive. The above embodiments can be modified and improved in various forms without departing from the scope and intent of the attached claims. The matters described in the above embodiments can be varied as long as there is no contradiction, or can be combined as long as there is no contradiction.

The substrate-treatment apparatus of the present disclosure is not limited to the processors 101 and 102, but is applicable as any type of apparatuses of Atomic Layer Deposition (ALD), Capacitively Coupled Plasma (CCP), Inductively Coupled Plasma (ICP), Radial Line Slot Antenna (RLSA), Electron Cyclotron Resonance Plasma (ECR), and Helicon Wave Plasma (HWP).

According to an aspect of the present disclosure, it is possible to realize a desired substrate treatment while protecting a side wall of a recess in a silicon nitride-containing film formed at a substrate.

What is claimed is:

1. A substrate-treatment method, comprising:
(a) providing a substrate at a stage, the substrate including a silicon nitride-containing film, in which a recess defined by a top, a side wall, and a bottom is formed, and a silicon film exposed from the bottom of the recess;
(b) forming a silicon oxide film along the recess;
(c) exposing the silicon oxide film to a plasma of a process gas containing a hydrogen gas, thereby modifying the silicon oxide film at the top and bottom of the recess selectively relative to the side wall by an anisotropic plasma treatment; and
(d) selectively removing the modified silicon oxide film at the top and bottom of the recess through chemical etching without using a plasma, thereby retaining the silicon oxide film at the side wall of the recess.

2. The substrate-treatment method according to claim 1, wherein
(b), (c), and (d) are repeatedly performed in an order of (b), (c), and (d).

3. The substrate-treatment method according to claim 1, further comprising:
after (d), (e) forming a metal film at the bottom of the recess.

4. The substrate-treatment method according to claim 3, further comprising:
after (e), (f) removing the silicon oxide film at the side wall.

5. The substrate-treatment method according to claim 4, further comprising:
after (e) yet before (f), (g) reacting the metal film with the silicon film exposed from the bottom of the recess, thereby forming a metal silicate.

6. The substrate-treatment method according to claim 1, wherein
(c) includes supplying an RF power to the stage.

7. The substrate-treatment method according to claim 6, wherein
(c) supplies the RF power that is 100 W to 500 W.

8. The substrate-treatment method according to claim 1, wherein
(b) forms the silicon oxide film through thermal CVD, plasma CVD, thermal ALD, or plasma ALD.

9. The substrate-treatment method according to claim 1, wherein
(b) forms the silicon oxide film to be conformal.

10. The substrate-treatment method according to claim 1, wherein
(c) supplies a microwave power to a process chamber, thereby generating the plasma of the process gas containing the hydrogen gas.

11. The substrate-treatment method according to claim 1, wherein
(d) includes
supplying a process gas containing fluorine and hydrogen to fluorinate the modified silicon oxide film at the top and bottom of the recess, thereby forming a fluoride, and
sublimating the fluoride through heating,
thereby removing the silicon oxide film at the top and bottom of the recess through chemical etching.

12. The substrate-treatment method according to claim 3, wherein
(e) forms the metal film through thermal CVD, plasma CVD, thermal ALD, or plasma ALD.

13. The substrate-treatment method according to claim 3, wherein
the metal film is a titanium film.

14. The substrate-treatment method according to claim 1, wherein
(c) controls an internal pressure of a process chamber, into which the process gas is supplied, to be 5 Pa to 133.3 Pa.

15. A substrate-treatment system, comprising:
a plurality of process chambers;
a vacuum transfer chamber configured to transfer a substrate in vacuum between the plurality of process chambers; and
a controller including a memory and a processor connected to the memory, the processor being configured to control a process including
providing the substrate at a stage of a first process chamber of the plurality of process chambers and forming a silicon oxide film along a recess, the substrate including a silicon nitride-containing film, in which the recess defined by a top, a side wall, and a bottom is formed, and a silicon film exposed from the bottom of the recess,
after the formation of the silicon oxide film, providing the substrate at a stage of a second process chamber of the plurality of process chambers, exposing the silicon oxide film to a plasma of a process gas containing a hydrogen gas, and modifying the silicon oxide film at the top and bottom of the recess selectively relative to the side wall by an anisotropic plasma treatment,
after the selective modification of the silicon oxide film, providing the substrate at a stage of a third process chamber of the plurality of process chambers, supplying a process gas containing fluorine and hydrogen to fluorinate the modified silicon oxide film at the top and bottom of the recess, thereby forming a fluoride,
after the formation of the fluoride, providing the substrate at a stage of a fourth process chamber of the plurality of process chambers and sublimating the fluoride through heating, and
removing the silicon oxide film at the top and bottom of the recess through chemical etching, thereby retaining the silicon oxide film at the side wall of the recess.
